(19) United States
(12) Patent Application Publication
(10) Pub. No.: US 2006/0208318 A1
(43) Pub. Date: Sep. 21, 2006

(54) MOS field effect semiconductor device and method for fabricating the same

(75) Inventors: Manabu Sakamoto, Kawasaki (JP); Teruo Kurahashi, Kawasaki (JP); Yasuyoshi Mishima, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/370,885

(22) Filed: Mar. 9, 2006

(30) Foreign Application Priority Data
Dec. 16, 2005 (JP) 2005-363112
Mar. 18, 2005 (JP) 2005-079751

(51) Int. Cl. H01L 29/78; H01L 21/8238

(52) U.S. Cl. 257/369; 257/412; 257/407; 438/199; 438/592

(57) ABSTRACT

A high-performance CMOS field effect semiconductor device using metal gate electrodes. An n-type gate electrode and a p-type gate electrode are formed by using a same metal and differ in nitrogen concentration. As a result, a high-performance CMOS field effect semiconductor device having the n-type gate electrode and the p-type gate electrode between which a work function difference is a predetermined value can be realized. By forming a low-resistance layer on layers which are formed by using the same metal and which differ in nitrogen concentration, it is possible to reduce the resistance of the n-type gate electrode and the p-type gate electrode while controlling the work functions of the n-type gate electrode and the p-type gate electrode. Therefore, a higher-performance CMOS field effect semiconductor device can be realized.

### CROSS-REFERENCE TO RELATED APPLICATIONS

This application is based upon and claims the benefits of priority from the prior Japanese Patent Application Nos. 2005-79751, filed on Mar. 18, 2005, and 2005-363112, filed on Dec. 16, 2005, the entire contents of which are incorporated herein by reference.

### BACKGROUND OF THE INVENTION

(1) Field of the Invention

This invention relates to a MOS field effect semiconductor device and a method for fabricating such a MOS field effect semiconductor device and, more particularly, to a MOS field effect semiconductor device including an n-type gate electrode and a p-type gate electrode between which a difference in work function is needed and a method for fabricating such a MOS field effect semiconductor device.

(2) Description of the Related Art

To form gate electrodes in a MOS field effect semiconductor device, impurities have conventionally been introduced into polycrystalline silicon gate electrodes. By doing so, an n-type gate electrode and a p-type gate electrode are formed and a difference in work function between them is about 1 eV.

Even if metal gate electrodes are formed, a work function difference of about 1 eV is needed between an n-type metal gate electrode and a p-type metal gate electrode to maintain channel impurity concentration and an impurity concentration profile used for conventional polycrystalline silicon gate electrodes.

Unlike the case where different kinds of impurities are introduced into polycrystalline silicon gate electrodes to form an n-type gate electrode and a p-type gate electrode, however, different materials must be used for forming an n-type metal gate electrode and a p-type metal gate electrode. By doing so, a difference in work function, and therefore a difference in threshold voltage, is obtained. In this case, however, it is impossible to avoid an increase in the number of manufacturing processes or a drop in a manufacturing yield.

By the way, in recent years it has been reported that a work function can be changed by nitriding a metal gate electrode (see, for example, Japanese Patent Laid-Open Publication No. 2000-31296 and “Robust High-Quality HfN—HfO₂ Gate Stack for Advanced MOS Device Applications,” IEEE Electron Device Letters, vol. 25, No. 2, February 2004).

Under the existing circumstances, however, a concrete method for obtaining work functions which meet n-type silicon and p-type silicon is not known. Moreover, a work function control range (ΔV_{FB}) is unknown. As a result, the work function control range of an n-type gate electrode or a p-type gate electrode obtained by nitriding a metal gate electrode and nitrogen concentration in the n-type gate electrode and the p-type gate electrode are also unknown.

Therefore, at present it is impossible to fabricate a practical MOS field effect semiconductor device by utilizing the technique for changing a work function by nitriding a metal gate electrode.

### SUMMARY OF THE INVENTION

By the present invention, a work function difference of 1 eV is realized between an n-type metal gate electrode and a p-type metal gate electrode in a MOS field effect semiconductor device made of the same material, and the advantage of being able to maintain channel impurity concentration and impurity concentration profiles for conventional polycrystalline silicon gate electrodes is obtained.

An object of the present invention is to provide a high performance MOS field effect semiconductor device using metal gate electrodes and a method for fabricating such a MOS field effect semiconductor device.

In order to achieve the above object, a method for fabricating a complementary MOS field effect semiconductor device is provided. This method comprises the steps of forming a gate insulating film on an n-type MOS transistor formation region and a p-type MOS transistor formation region in a semiconductor layer; forming work function control layers which differ in nitrogen concentration on the gate insulating film on the n-type MOS transistor formation region and on the gate insulating film on the p-type MOS transistor formation region; and forming a low-resistance layer on the work function control layers.

Furthermore, in order to achieve the above object, a MOS field effect semiconductor device in which an n-type gate electrode and a p-type gate electrode formed on a gate insulating film on a semiconductor layer having an n-type active region and a p-type active region are made of a same metal and in which nitrogen concentration at an interface between the metal and the gate insulating film differs between the n-type gate electrode and the p-type gate electrode is provided.

In addition, in order to achieve the above object, a complementary MOS field effect semiconductor device is provided. In this complementary MOS field effect semiconductor device, each of an n-type gate electrode and a p-type gate electrode has a work function control layer formed by using a same metal, a low-resistance layer is formed on the work function control layer in the n-type gate electrode by using metal resistance of which is lower than resistance of the work function control layer in the n-type gate electrode, and a low-resistance layer is formed on the work function control layer in the p-type gate electrode by using metal resistance of which is lower than resistance of the work function control layer in the p-type gate electrode.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 presents graphs each showing a profile of nitrogen concentration in hafnium.

FIG. 2 presents a graph showing the relationship between nitrogen concentration and a work function.

FIG. 3 shows C-V characteristics.

FIG. 4 shows the relationship between the work function control range and resistivity of a metal gate electrode.

FIG. 5 is a schematic view of an example of a MOS structure in which a two-layer metal gate electrode is used.

FIG. 6 is a schematic sectional view showing an important part of a MOS structure in which an n-type two-layer metal gate electrode is used.

FIG. 7 shows results obtained by measuring the resistivity of the n-type two-layer metal gate electrode.

FIG. 8 is a schematic sectional view showing an important part of a MOS structure in which a p-type two-layer metal gate electrode is used.

FIG. 9 shows results obtained by measuring the resistivity of the p-type two-layer metal gate electrode.

FIG. 10 is a schematic sectional view showing an important part of an HfN layer formation process in a first example.

FIG. 11 is a schematic sectional view showing an important part of a nitrogen introduction process in the first example.

FIG. 12 is a schematic sectional view showing an important part of a low-resistance layer formation process in the first example.

FIG. 13 is a schematic sectional view showing an important part of a gate fabrication process in the first example.

FIG. 14 is a schematic sectional view showing an important part of an HfN layer formation process in a second example.

FIG. 15 is a schematic sectional view showing an important part of a nitrogen introduction process in the second example.

FIG. 16 is a schematic sectional view showing an important part of a low-resistance layer formation process in the second example.

FIG. 17 is a schematic sectional view showing an important part of a gate fabrication process in the second example.

FIG. 18 is a schematic sectional view showing an important part of a transistor structure formation process in the second example.

### DESCRIPTION OF THE PREFERRED EMBODIMENTS

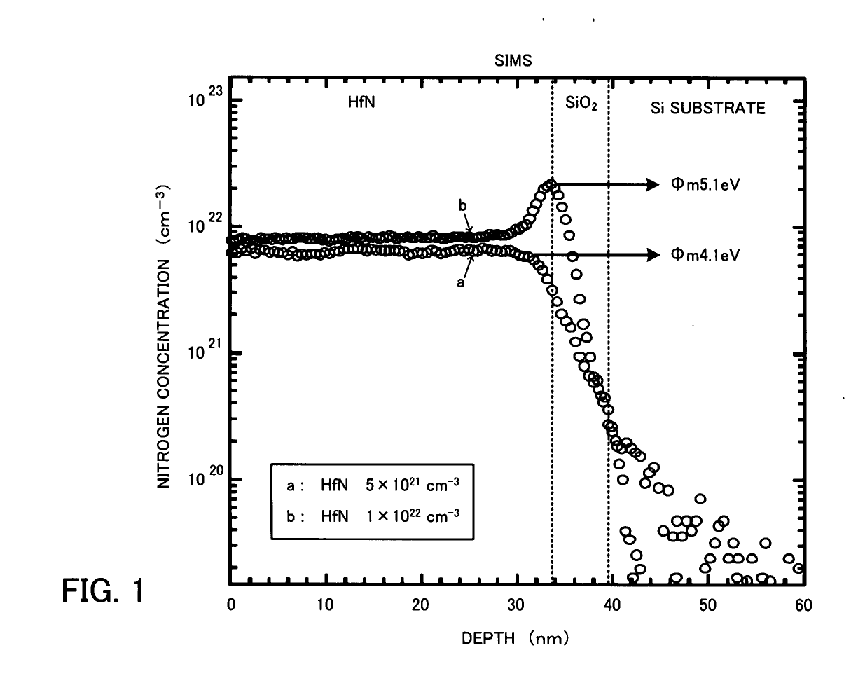

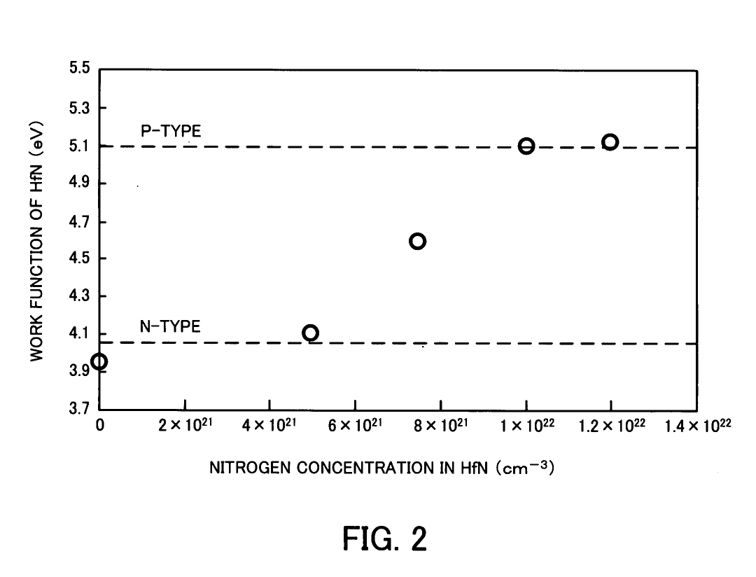

FIG. 1 presents graphs each showing a profile of nitrogen concentration in hafnium. FIG. 2 is a graph showing the relationship between nitrogen concentration and a work function. FIG. 1 shows results obtained by performing secondary ion mass spectrometry (SIMS) on nitrogen in the hafnium (Hf) in the direction of depth. In FIG. 1, a horizontal axis indicates depth (nm) and a vertical axis indicates nitrogen concentration (cm⁻³). In FIG. 2, a horizontal axis indicates nitrogen concentration (cm⁻³) in hafnium nitride (HfN) and a vertical axis indicates the work function (eV) of HfN.

When experiments were done to obtain the data shown in FIGS. 1 and 2, a work function difference of 0.8 eV or more could be realized for HfN by introducing nitrogen into an n-type gate electrode made of hafnium (Hf) at a concentration of 5×10²¹ cm⁻³ and by introducing nitrogen into a p-type gate electrode made of the same material at a concentration of 1×10²² cm⁻³.

That is to say, for example, the work function of HfN becomes 4.1 eV by making nitrogen concentration in hafnium 5×10²¹ cm⁻³ and the work function of HfN becomes 5.1 eV by making nitrogen concentration in hafnium 1×10²² cm⁻³.

Even if metal gate electrodes are made of the same material, a work function difference can be given in this way. Therefore, the same channel impurity concentration and impurity concentration profiles that are adopted for ordinary polycrystalline silicon gate electrodes can be used.

It is obvious from FIG. 1 that nitrogen is accumulated in the hafnium near the interface between the hafnium and the gate insulating film (silicon oxide (SiO₂) film) and that a work function difference can efficiently be realized.

In addition, it is obvious from FIG. 2 that if nitrogen concentration is low or high, the same work functions that are obtained by using conventional polycrystalline silicon gate electrodes cannot be realized.

In the above example, hafnium is used. However, if zirconium (Zr) is used, the same results can be obtained. That is to say, a work function difference of 0.8 eV or more could be obtained for zirconium nitride (ZrN) by introducing nitrogen into an interface between an n-type gate electrode and a gate insulating film at a concentration of 5×10²¹ cm⁻³ and by introducing nitrogen into an interface between a p-type gate electrode and the gate insulating film at a concentration of 1×10²² cm⁻³.

### EXAMPLE

An HfN (nitrogen concentration is 5×10²¹ cm⁻³) film is formed as a gate electrode film. Only n-type gate electrode is covered with a protection film, such as a resist film, and p-type gate electrode is exposed. Nitrogen (N) ions are implanted in the p-type gate electrode by an ion implantation method so that nitrogen concentration will be 1×10²² cm⁻³. Heat treatment is then performed at a temperature of 500° C. for about 30 minutes.

As a result, nitrogen concentration at an interface between the n-type gate electrode made of HfN and a gate insulating film is 5×10²¹ cm⁻³ and nitrogen concentration at an interface between the p-type gate electrode made of HfN and the gate insulating film is 1×10²² cm⁻³.

By changing nitrogen concentration in the same metal in this way, a work function difference of 1 eV can be realized between the n-type gate electrode and the p-type gate electrode. In addition, if a molybdenum nitride (MoN) film is formed on the HfN film to form a two-layer structure, the oxidation of HfN can be prevented. As a result, the HfN film can withstand heat treatment performed in a later process and a CMOS field effect semiconductor device having high-performance metal gate electrodes can be provided. Moreover, if the MoN film is formed on the HfN film to form a two-layer structure, the resistance of the gate electrodes can be reduced. This will be described later.

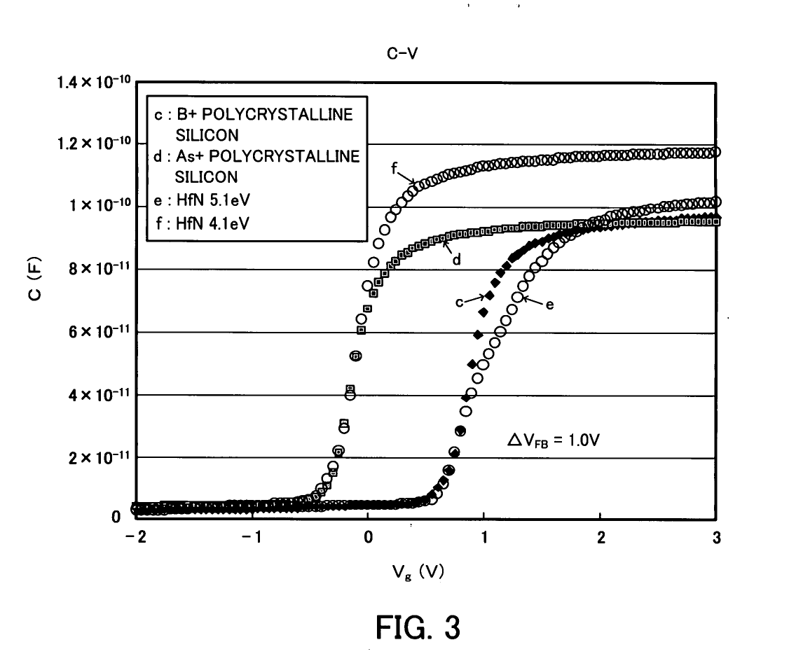

FIG. 3 presents graphs showing the C-V characteristic of a MOS diode having HfN gate electrodes according to the present invention and the C-V characteristic of conventional polycrystalline silicon gate electrodes for comparison. In FIG. 3, a horizontal axis indicates gate voltage Vg (V) and a vertical axis indicates capacitance C (F).

As can be seen from FIG. 3, V_{FB} of a p-type gate electrode (shown by graph c) made of polycrystalline silicon doped with boron (B⁺) is the same as V_{FB} of a p-type gate electrode (shown by graph e) of HfN in which nitrogen concentration is 1×10²² cm⁻³ at an interface between the p-type gate electrode and a gate insulating film. In addition, V_{FB} of an n-type gate electrode (shown by graph d) made of polycrystalline silicon doped with arsenic (As⁺) is the same as V_{FB} of an n-type gate electrode (shown by graph f) of HfN in which nitrogen concentration is 5×10²¹ cm⁻³ at an interface between the n-type gate electrode and the gate insulating film.

As shown in FIG. 2, with HfN, a work function tends to increase with an increase in nitrogen concentration. A work function significantly changes when nitrogen concentration is especially between 5×10²¹ cm⁻³ and 1×10²² cm⁻³. If nitrogen concentration in HfN of which an n-type gate electrode is made is lower than or equal to 5×10²¹ cm⁻³ and nitrogen concentration in HfN of which a p-type gate electrode is made is higher than or equal to 1×10²² cm⁻³, then a work function difference obtained may exceed a work function difference obtained by using polycrystalline silicon for forming both an n-type gate electrode and a p-type gate electrode. As stated above, however, by setting nitrogen concentration in HfN of which an n-type gate electrode is made and nitrogen concentration in HfN of which a p-type gate electrode is made to, for example, 5×10²¹ cm⁻³ and 1×10²² cm⁻³ respectively, the same work function difference that is obtained by using polycrystalline silicon for forming both an n-type gate electrode and a p-type gate electrode can be realized.

The resistance of a metal gate electrode will now be described.

As mentioned above, when a metal gate electrode is nitrided, a work function can be controlled by changing the concentration of nitrogen introduced. By introducing nitrogen, however, the resistance of the metal gate electrode increases.

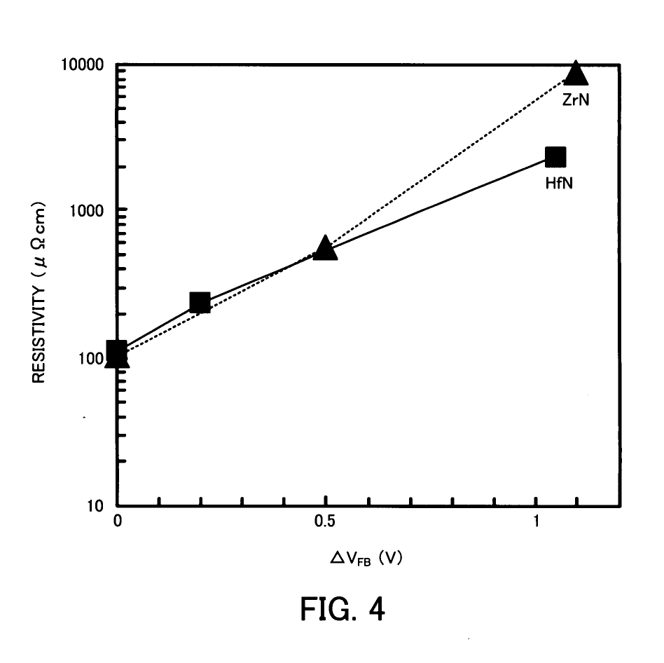

FIG. 4 shows the relationship between the work function control range and resistivity of a metal gate electrode. In FIG. 4, a horizontal axis indicates a work function control range ΔV_{FB} (V) and a vertical axis indicates resistivity (μΩcm).

As can be seen from FIG. 4, an increase in the work function control range ΔV_{FB} of HfN or ZrN, that is to say, an increase in the amount of nitrogen introduced into Hf or Zr causes a rise in the resistivity of HfN or ZrN. Accordingly, an increase in the amount of nitrogen introduced causes a rise in the resistivity of a metal gate electrode.

In this case, a gate electrode (hereinafter referred to as “the two-layer metal gate electrode”) where a low-resistance metal or metal nitride (hereinafter simply referred to as “metal”) layer is formed on an HfN or ZrN layer is fabricated in order to suppress such an increase in resistance which takes place in the case of using HfN or ZrN as a gate electrode.

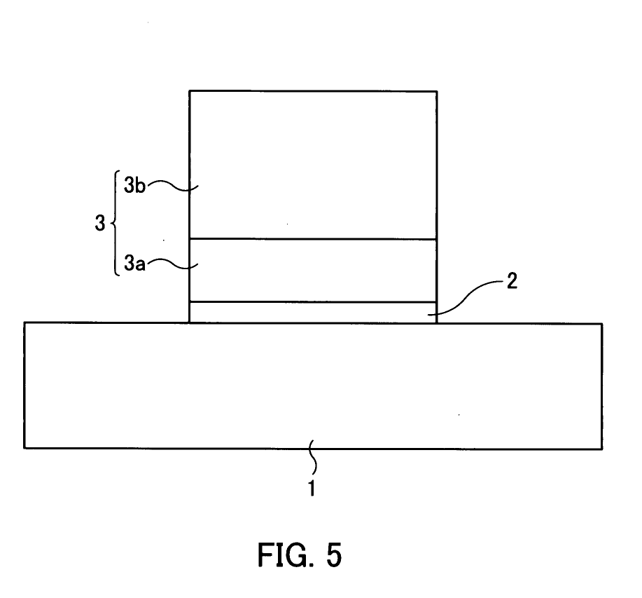

FIG. 5 is a schematic view of an example of a MOS structure in which a two-layer metal gate electrode is used.

In a MOS structure shown in FIG. 5, a two-layer metal gate electrode 3 is formed over a silicon substrate 1 with a gate insulating film 2 made of, for example, SiO₂ between. In the two-layer metal gate electrode 3, a layer (hereinafter referred to as “the work function control layer”) 3a for controlling a work function is formed as a lower layer and a layer (hereinafter referred to as “the low-resistance layer”) 3b for lowering the resistance of the gate electrode is formed as an upper layer.

An HfN layer or a ZrN layer in which nitrogen concentration is the above predetermined value can be used as the work function control layer 3a. That is to say, to form the n-type two-layer metal gate electrode 3, an HfN layer or a ZrN layer in which nitrogen concentration is lower than or equal to 5×10²¹ cm⁻³ can be used as the work function control layer 3a. To form the p-type two-layer metal gate electrode 3, an HfN layer or a ZrN layer in which nitrogen concentration is higher than or equal to 1×10²² cm⁻³ can be used as the work function control layer 3a.

Metal made of one or more of low-resistance metals, such as niobium (Nb), tantalum (Ta), tungsten (W), iron (Fe), molybdenum (Mo), copper (Cu), osmium (Os), ruthenium (Ru), rhodium (Rh), cobalt (Co), gold (Au), nickel (Ni), iridium (Ir), and platinum (Pt), or a nitride which contains the metal can be used as the low-resistance layer 3b. The resistivity of such metal is lower than that of an HfN layer or a ZrN layer. Furthermore, the melting point of such metal is higher than or equal to 1,000° C., so it is stable in a heat treatment process performed later.

The above MOS structure is formed in, for example, the following way. The gate insulating film 2 made of SiO₂ is formed on the silicon substrate 1 by an ordinary method. An HfN layer or a ZrN layer is then formed as the work function control layer 3a by a sputtering method or a chemical vapor deposition (CVD) method. When occasion demands, nitrogen is introduced by an ion implantation method to make nitrogen concentration in the HfN layer or the ZrN layer the predetermined value. Alternatively, nitrogen may be introduced by the ion implantation method into an Hf layer or a Zr layer previously formed to form an HfN layer or a ZrN layer in which nitrogen concentration is the predetermined value. After the work function control layer 3a is formed in this way, a metal layer is formed as the low-resistance layer 3b by the sputtering method or the CVD method. Finally, a proper gate fabrication process should be performed to form the two-layer metal gate electrode 3 having a predetermined shape on the gate insulating film 2.

A high-dielectric-constant (high-k) material, such as silicon oxide nitride (SiON), hafnium oxide (HfO₂), or hafnium silicate (HfSiO), can be used in place of SiO₂ for forming the gate insulating film 2. In this case, the two-layer metal gate electrode 3 can be formed in the same way as described above.

The effect of reducing the resistance of the gate electrode by the formation of the low-resistance layer 3b will now be described by giving a concrete example.

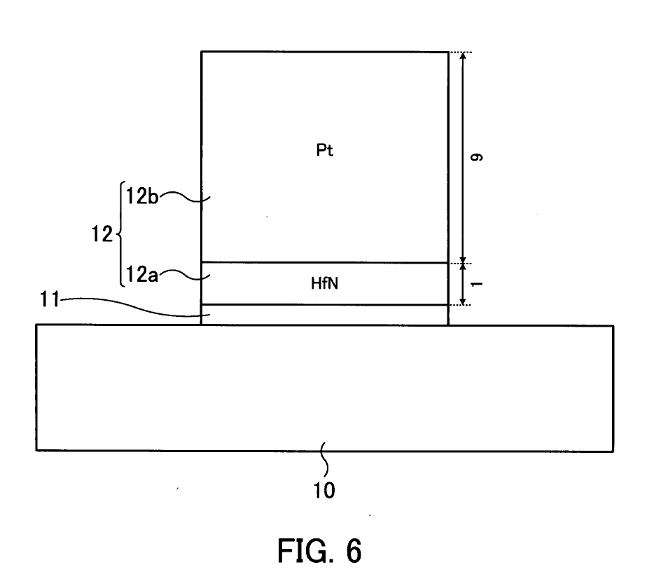

FIG. 6 is a schematic sectional view showing an important part of a MOS structure in which an n-type two-layer metal gate electrode is used.

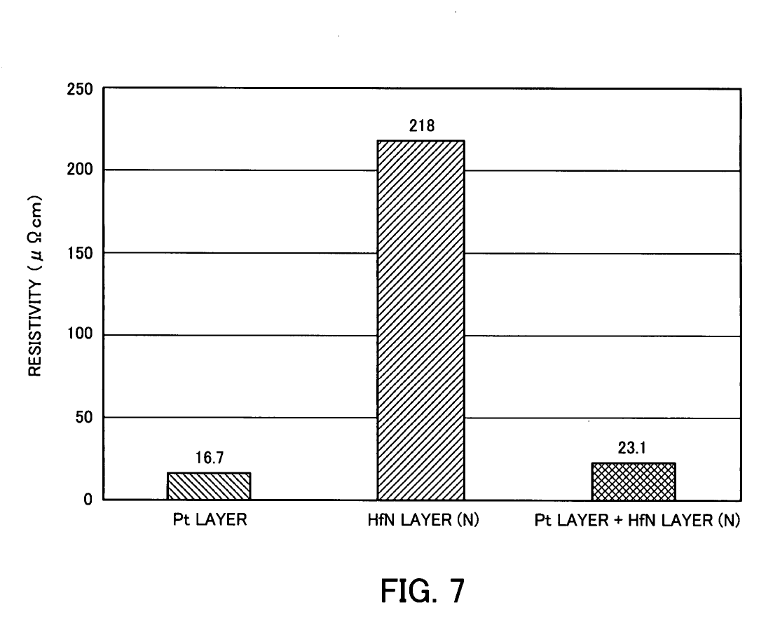

In a MOS structure shown in FIG. 6, an n-type two-layer metal gate electrode 12 in which a Pt layer 12b, being a low-resistance layer, is formed on an HfN layer 12a, being a work function control layer, is formed over a silicon substrate 10 with a gate insulating film 11 between. The concentration of nitrogen which has been introduced into the HfN layer 12a in the n-type two-layer metal gate electrode 12 is 5×10²¹ cm⁻³. The ratio of the thickness of the HfN layer 12a to the thickness of the Pt layer 12b formed thereon is set to 1 to 9 (thickness of HfN layer:thickness of Pt layer=1:9). Results obtained by measuring the resistivity of the n-type two-layer metal gate electrode 12 having the above structure are shown in FIG. 7.

FIG. 7 shows results obtained by measuring the resistivity of the n-type two-layer metal gate electrode. In addition to results obtained by measuring the resistivity of the n-type two-layer metal gate electrode 12, results obtained by measuring the resistivity of the HfN layer 12a and the Pt layer 12b which are individually formed on the gate insulating film 11 on the silicon substrate 10 are shown in FIG. 7. In this case, nitrogen concentration in the HfN layer 12a corresponds to nitrogen concentration in an n-type gate electrode.

As can be seen from FIG. 7, the resistivity of the Pt layer 12b (indicated by “Pt layer” in FIG. 7) is 16.7 μΩcm and the resistivity of the HfN layer 12a (indicated by “HfN layer (n) in FIG. 7) in which nitrogen concentration corresponds to nitrogen concentration in an n-type gate electrode is 218 μΩcm. The resistivity of the n-type two-layer metal gate electrode 12 (indicated by “Pt layer+HfN layer (n)” in FIG. 7) in which the Pt layer 12b is formed on the HfN layer 12a is 23.1 μΩcm.

By forming the Pt layer 12b on the HfN layer 12a in this way, resistivity significantly drops from 218 μΩcm to 23.1 μΩcm. The resistivity of the n-type two-layer metal gate electrode 12 is almost the same as that of the Pt layer 12b alone. As a result, it is ascertained that a work function is controlled by nitrogen concentration and that a metal gate electrode having very low resistance is formed.

In the above example, the ratio of the thickness of the HfN layer 12a to the thickness of the Pt layer 12b is 1 to 9. As a result of making measurements in the same way while varying this ratio, the resistivity of the n-type two-layer metal gate electrode 12 demonstrated a tendency to rise with an increase in the ratio of the thickness of the HfN layer 12a to the thickness of the Pt layer 12b. In addition, as a result of using other metal materials for forming a low-resistance layer included in the n-type two-layer metal gate electrode 12 and making measurements in the same way, resistance can be reduced by forming the low-resistance layer on the HfN layer 12a, compared with the case where only the HfN layer 12a is formed. In this case, the resistivity of the n-type two-layer metal gate electrode 12 also demonstrated a tendency to rise with an increase in the ratio of the thickness of the HfN layer 12a to the thickness of the low-resistance layer.

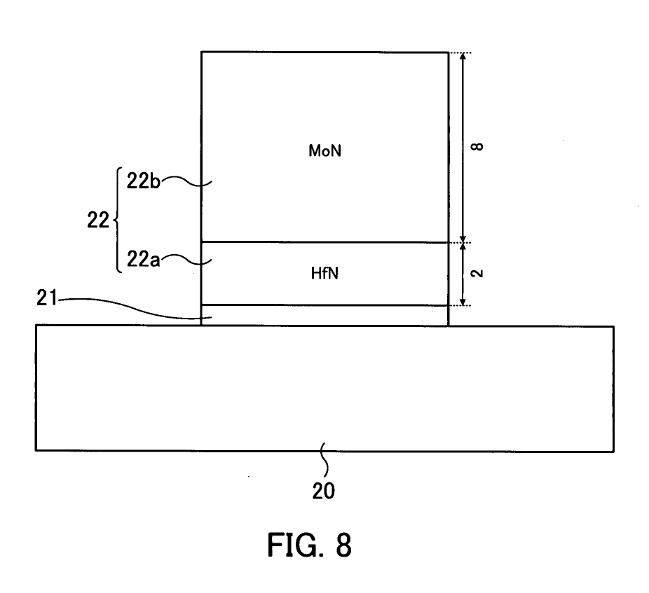

FIG. 8 is a schematic sectional view showing an important part of a MOS structure in which a p-type two-layer metal gate electrode is used.

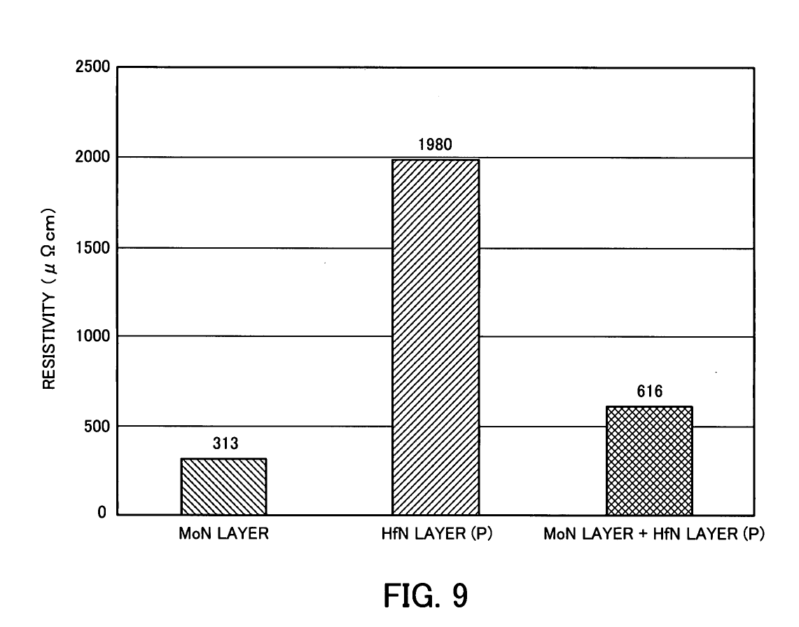

In a MOS structure shown in FIG. 8, a p-type two-layer metal gate electrode 22 in which an MoN layer 22b, being a low-resistance layer, is formed on an HfN layer 22a, being a work function control layer, is formed over a silicon substrate 20 with a gate insulating film 21 between. The concentration of nitrogen which has been introduced into the HfN layer 22a in the p-type two-layer metal gate electrode 22 is 1×10²² cm⁻³. The ratio of the thickness of the HfN layer 22a to the thickness of the MoN layer 22b formed thereon is set to 2 to 8 (thickness of HfN layer:thickness of MoN layer=2:8). Results obtained by measuring the resistivity of the p-type two-layer metal gate electrode 22 having the above structure are shown in FIG. 9.

FIG. 9 shows results obtained by measuring the resistivity of the p-type two-layer metal gate electrode. In addition to results obtained by measuring the resistivity of the p-type two-layer metal gate electrode 22, results obtained by measuring the resistivity of the HfN layer 22a and the MoN layer 22b which are individually formed on the gate insulating film 21 on the silicon substrate 20 are shown in FIG. 9. In this case, nitrogen concentration in the HfN layer 22a corresponds to nitrogen concentration in a p-type gate electrode.

As can be seen from FIG. 9, the resistivity of the MoN layer 22b (indicated by “MoN layer” in FIG. 9) is 313 μΩcm and the resistivity of the HfN layer 22a (indicated by “HfN layer (p) in FIG. 9) nitrogen concentration in which corresponds to nitrogen concentration in a p-type gate electrode is 1,980 μΩcm. The resistivity of the p-type two-layer metal gate electrode 22 (indicated by “MoN layer+HfN layer (p)” in FIG. 9) in which the MoN layer 22b is formed on the HfN layer 22a is 616 μΩcm.

By forming the MoN layer 22b on the HfN layer 22a in this way, resistivity significantly drops from 1,980 μΩcm to 616 μΩcm. As a result, it is ascertained that a work function is controlled by nitrogen concentration and that a metal gate electrode having very low resistance is formed.

In the above example, the ratio of the thickness of the HfN layer 22a to the thickness of the MoN layer 22b is 2 to 8. As a result of making measurements in the same way while varying this ratio, the resistivity of the p-type two-layer metal gate electrode 22 demonstrated a tendency to rise with an increase in the ratio of the thickness of the HfN layer 22a to the thickness of the MoN layer 22b. In addition, as a result of using other metal materials for forming a low-resistance layer included in the p-type two-layer metal gate electrode 22 and making measurements in the same way, resistance can be reduced by forming the low-resistance layer on the HfN layer 22a, compared with the case where only the HfN layer 22a is formed. In this case, the resistivity of the p-type two-layer metal gate electrode 22 also demonstrated a tendency to rise with an increase in the ratio of the thickness of the HfN layer 22a to the thickness of the low-resistance layer.

The flow of processes for fabricating a CMOS field effect semiconductor device using two-layer metal gate electrodes will now be described.

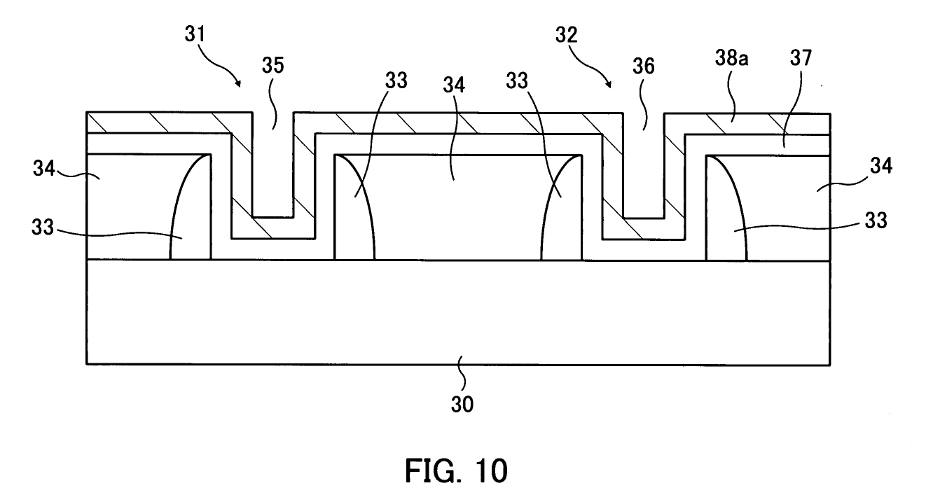

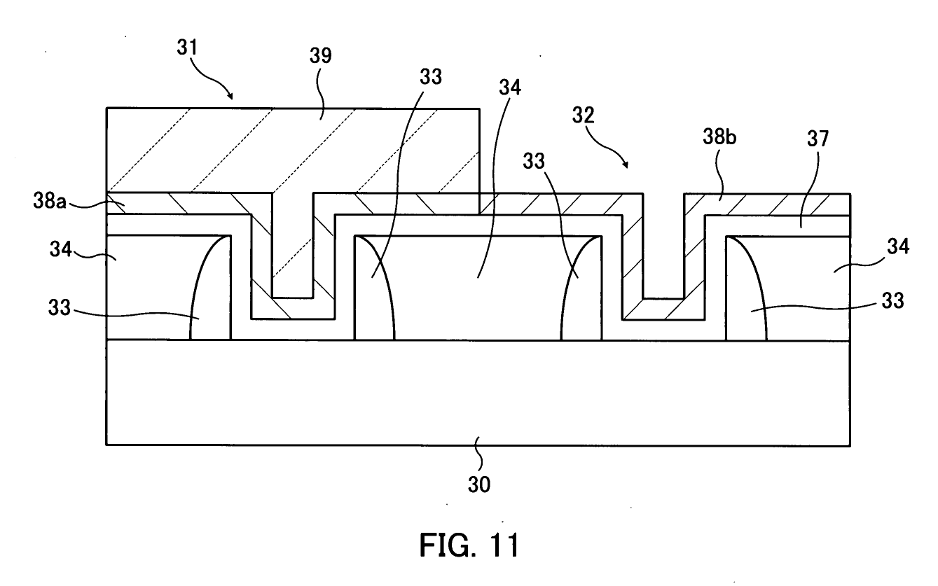

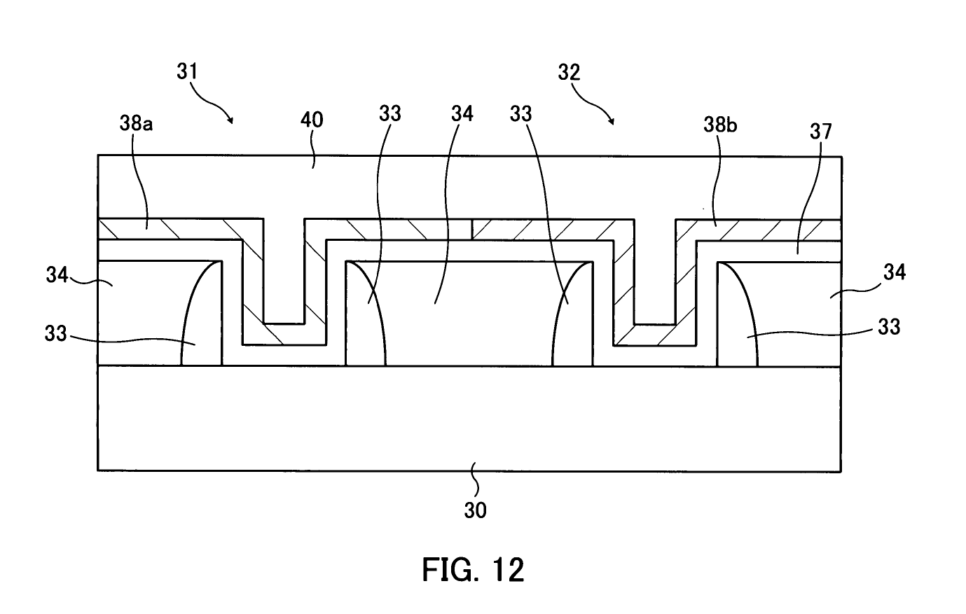

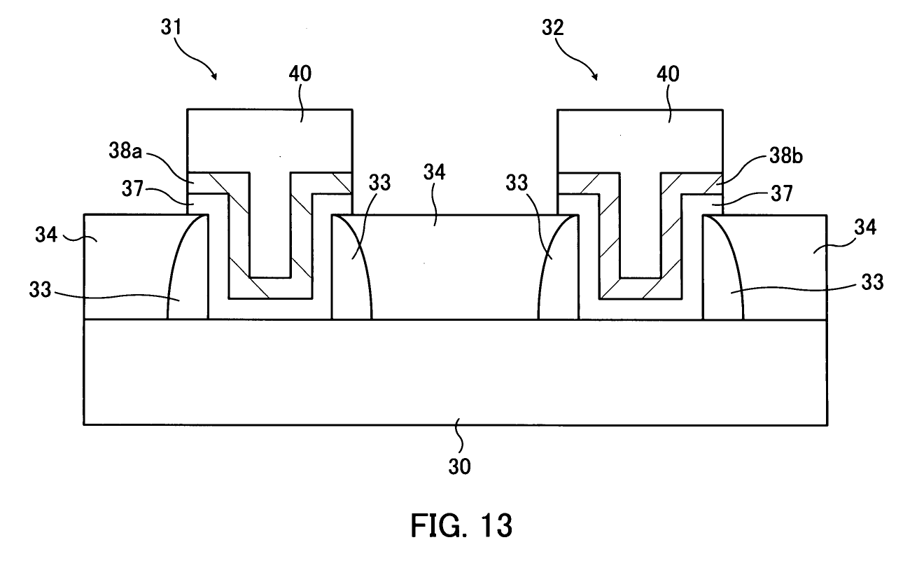

FIGS. 10 through 13 are views for describing a first example of the flow of processes for fabricating a CMOS field effect semiconductor device. FIG. 10 is a schematic sectional view showing an important part of an HfN layer formation process in the first example. FIG. 11 is a schematic sectional view showing an important part of a nitrogen introduction process in the first example. FIG. 12 is a schematic sectional view showing an important part of a low-resistance layer formation process in the first example. FIG. 13 is a schematic sectional view showing an important part of a gate fabrication process in the first example.

In the first example of the flow of processes for fabricating a CMOS field effect semiconductor device, a method which has conventionally been known is used first for forming a p-type well (not shown) in an n-type MOS transistor formation region 31 in a silicon substrate 30 in which isolation regions (not shown) are formed and for forming an n-type well (not shown) in a p-type MOS transistor formation region 32 in the silicon substrate 30. After dummy gate electrodes (not shown) are formed, source/drain extension regions (not shown) are formed. Sidewalls 33 are formed and source/drain regions (not shown) are formed. An interlayer dielectric film 34 is then formed. When occasion demands, the surface of the interlayer dielectric film 34 is polished so that the top of each dummy gate electrode will get exposed. The dummy gate electrodes are then removed. As a result, gate pattern concave portions 35 and 36 enclosed by the sidewalls 33 are formed in the n-type MOS transistor formation region 31 and the p-type MOS transistor formation region 32 respectively. Channel regions in the silicon substrate 30 get exposed in the bottoms of the concave portions 35 and 36.

The CVD method is then used for forming a gate insulating film 37 made of, for example, SiO₂ on an entire surface. The CVD method, for example, is used for forming an HfN layer 38a which has a thickness of about 10 nm and in which nitrogen concentration is 5×10²¹ cm⁻³ on the gate insulating film 37. As a result, a state shown in FIG. 10 arises.

As shown in FIG. 11, the n-type MOS transistor formation region 31 is then covered with a resist film 39. Nitrogen the amount of which corresponds to a concentration of 5×10²¹ cm⁻³ is introduced into the HfN layer 38a in the p-type MOS transistor formation region 32 by the ion implantation method to form an HfN layer 38b in which a nitrogen concentration of 1×10²² cm⁻³ is obtained by summing the amount of nitrogen the HfN layer 38a contains and the amount of nitrogen introduced this time. The resist film 39 is then removed. As a result, the HfN layers 38a and 38b each having the predetermined nitrogen concentration are formed in the n-type MOS transistor formation region 31 and the p-type MOS transistor formation region 32, respectively, as work function control layers.

As shown in FIG. 12, after the HfN layers 38a and 38b are formed, a Pt layer 40 with a thickness of about 90 nm over channel regions is formed on an entire surface by, for example, the CVD method. As shown in FIG. 13, gate fabrication is finally performed to electrically separate the n-type MOS transistor formation region 31 and the p-type MOS transistor formation region 32. As a result, a two-layer metal gate electrode including the HfN layer 38a in which nitrogen concentration is 5×10²¹ cm⁻³ and the Pt layer 40 is formed in the n-type MOS transistor formation region 31 and a two-layer metal gate electrode including the HfN layer 38b in which nitrogen concentration is 1×10²² cm⁻³ and the Pt layer 40 is formed in the p-type MOS transistor formation region 32. That is to say, the basic structure of a CMOS field effect semiconductor device having the two-layer metal gate electrodes which are shown in FIG. 13 and between which the work function difference is the predetermined value is completed.

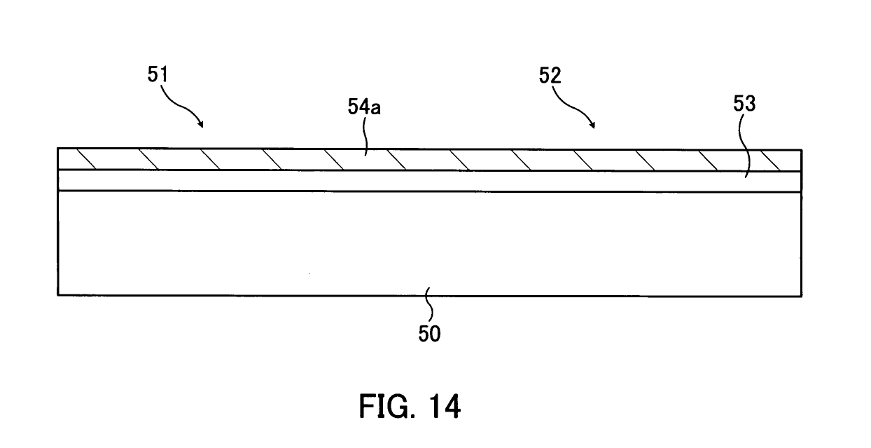

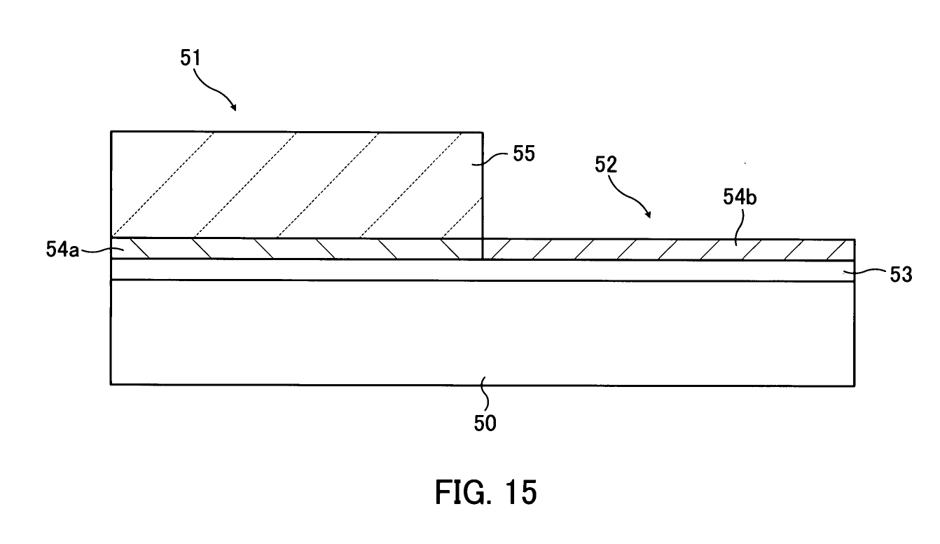

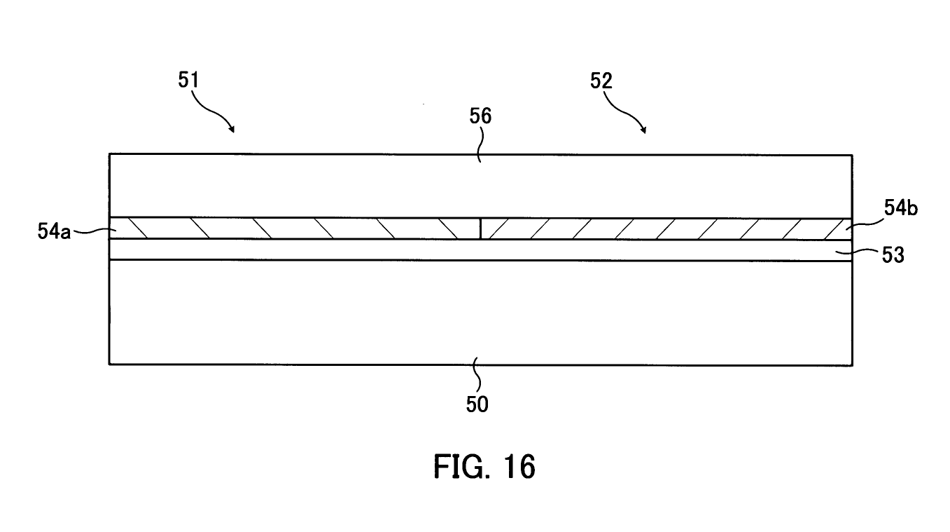

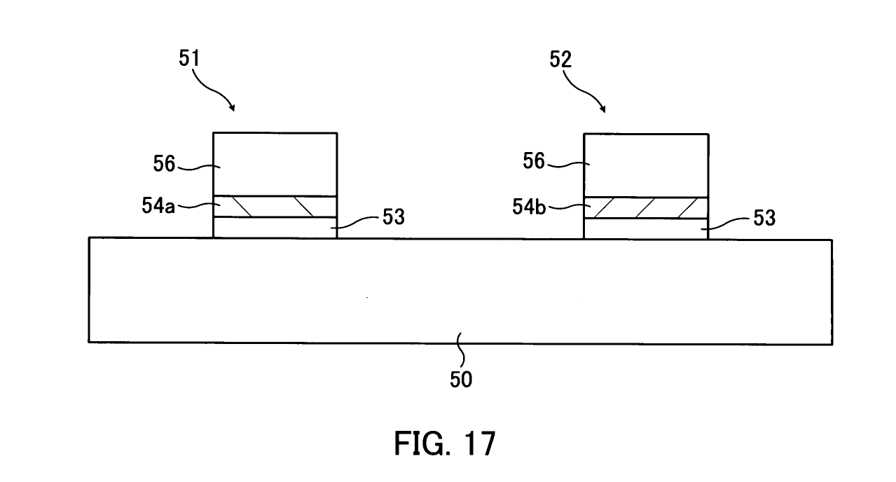

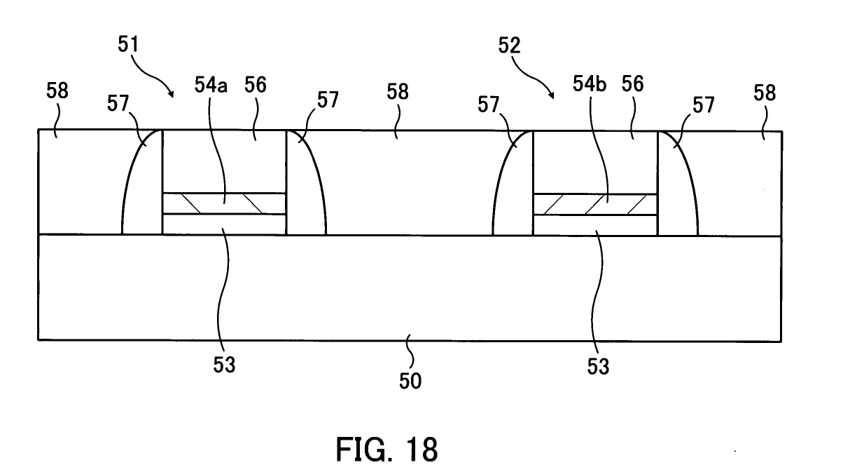

FIGS. 14 through 18 are views for describing a second example of the flow of processes for fabricating a CMOS field effect semiconductor device. FIG. 14 is a schematic sectional view showing an important part of an HfN layer formation process in the second example. FIG. 15 is a schematic sectional view showing an important part of a nitrogen introduction process in the second example. FIG. 16 is a schematic sectional view showing an important part of a low-resistance layer formation process in the second example. FIG. 17 is a schematic sectional view showing an important part of a gate fabrication process in the second example. FIG. 18 is a schematic sectional view showing an important part of a transistor structure formation process in the second example.

In the second example of the flow of processes for fabricating a CMOS field effect semiconductor device, a method which has conventionally been known is used first for forming a p-type well (not shown) in an n-type MOS transistor formation region 51 in a silicon substrate 50 in which isolation regions (not shown) are formed and for forming an n-type well (not shown) in a p-type MOS transistor formation region 52 in the silicon substrate 50. As shown in FIG. 14, a gate insulating film 53 made of SiO₂ is then formed on the silicon substrate 50 by, for example, a thermal oxidation method. After that, an HfN layer 54a which has a thickness of about 10 nm and in which nitrogen concentration is 5×10²¹ cm⁻³ is formed on an entire surface by, for example, the CVD method.

As shown in FIG. 15, the n-type MOS transistor formation region 51 is then covered with a resist film 55. Nitrogen the amount of which corresponds to a concentration of 5×10²¹ cm⁻³ is introduced into the HfN layer 54a in the p-type MOS transistor formation region 52 by the ion implantation method to form an HfN layer 54b in which a nitrogen concentration of 1×10²² cm⁻³ is obtained by summing the amount of nitrogen the HfN layer 54a contains and the amount of nitrogen introduced this time. The resist film 55 is then removed. As a result, the HfN layers 54a and 54b each having the predetermined nitrogen concentration are formed in the n-type MOS transistor formation region 51 and the p-type MOS transistor formation region 52, respectively, as work function control layers.

As shown in FIG. 16, after the HfN layers 54a and 54b are formed, a Pt layer 56 with a thickness of about 90 nm is formed on an entire surface by, for example, the CVD method. As shown in FIG. 17, gate fabrication is then performed on the HfN layer 54a in the n-type MOS transistor formation region 51, the HfN layer 54b in the p-type MOS transistor formation region 52, the Pt layer 56, and the gate insulating film 53. Finally, source/drain extension regions (not shown) are formed, sidewalls 57 are formed, source/drain regions (not shown) are formed, and an interlayer dielectric film 58 is formed.

As a result, a two-layer metal gate electrode including the HfN layer 54a in which nitrogen concentration is 5×10²¹ cm⁻³ and the Pt layer 56 is formed in the n-type MOS transistor formation region 51 and a two-layer metal gate electrode including the HfN layer 54b in which nitrogen concentration is 1×10²² cm⁻³ and the Pt layer 56 is formed in the p-type MOS transistor formation region 52. That is to say, the basic structure of a CMOS field effect semiconductor device having the two-layer metal gate electrodes which are shown in FIG. 18 and between which the work function difference is the predetermined value is completed.

As stated above, the CMOS field effect semiconductor device having the two-layer metal gate electrodes can be fabricated through the flow of the processes shown in the above first and second examples.

If a Pt layer is formed on an Hf layer, an alloy of Hf and Pt may be formed in a heat treatment process. In the above first and second examples, however, the Pt layer 40 is formed on the HfN layers 38a and 38b which contain nitrogen, and the Pt layer 56 is formed on the HfN layers 54a and 54b which contain nitrogen. Accordingly, an alloy of Hf and Pt is not formed in a heat treatment process and the two-layer structure of each gate electrode is maintained.

In the above first and second examples, HfN is used for forming work function control layers. However, ZrN may be used in place of HfN. In this case, a CMOS field effect semiconductor device can be fabricated by the same processes as described above. Moreover, in the above first and second examples, Pt is used for forming low-resistance layers. For example, however, various metals described above may be used in place of Pt. In this case, a CMOS field effect semiconductor device can be fabricated by the same processes as described above.

Furthermore, in each n-type two-layer metal gate electrode or each p-type two-layer metal gate electrode in the above first and second examples, HfN is used for forming a work function control layer and Pt is used for forming a low-resistance layer. However, a metal material used for forming a low-resistance layer included in an n-type two-layer metal gate electrode may differ from a metal material used for forming a low-resistance layer included in a p-type two-layer metal gate electrode.

That is to say, in an n-type two-layer metal gate electrode, metal the resistance of which is lower than that of a work function control layer is used for forming a low-resistance layer on the work function control layer. In a p-type two-layer metal gate electrode, metal the resistance of which is lower than that of a work function control layer is used for forming a low-resistance layer on the work function control layer. In the above first or second example, for example, such two-layer metal gate electrodes are formed in the following way. As shown in FIG. 12 or 16, after the Pt layer 40 or 56 is formed on the entire surface, the n-type MOS transistor formation region 31 or 51 is covered with, for example, a resist film and the Pt layer 40 or 56 in the p-type MOS transistor formation region 32 or 52 is removed. Another metal layer should be formed at a place where the Pt layer 40 or 56 is removed. Alternatively, after the process shown in FIG. 10 or 14 is performed, the Pt layer 40 or 56 is formed on an entire surface as shown in FIG. 12 or 16. The n-type MOS transistor formation region 31 or 51 is masked and the Pt layer 40 or 56 and the HfN layer 38a or 54a in the p-type MOS transistor formation region 32 or 52 are removed. The HfN layer 38b or 54b in which nitrogen concentration is a predetermined value is formed at a place where the Pt layer 40 or 56 and the HfN layer 38a or 54a are removed, and the Pt layer 40 or 56 is formed again on the HfN layer 38b or 54b.

As in the above first and second examples, however, if a CMOS field effect semiconductor device is fabricated, low-resistance layers in an n-type two-layer metal gate electrode and a p-type two-layer metal gate electrode should be formed by using the same metal. By doing so, a fabrication process can be simplified.

In addition, the thickness of each layer, conditions under which each layer is formed, and the like described in the above first and second examples are simple examples. They can be set appropriately according to the shape of a CMOS field effect semiconductor device to be fabricated or characteristics required.

In the above descriptions, HfN or ZrN is used for forming a work function control layer in each two-layer metal gate electrode. However, titanium nitride (TiN), tantalum nitride (TaN), MoN, tungsten nitride (WN), or the like may be used in place of HfN or ZrN. In addition, metal made of one or more of Hf, Zr, titanium (Ti), Ta, Mo, and W or a nitride which contains two or more of Hf, Zr, Ti, Ta, Mo, and W may be used.

As has been described in the foregoing, in the present invention an n-type gate electrode and a p-type gate electrode the work function difference between which is 1 eV can easily be realized by using the same metal that differs in nitrogen concentration.

Moreover, in the present invention each of an n-type gate electrode and a p-type gate electrode includes a work function control layer and a low-resistance layer formed thereon. As a result, it is possible to reduce the resistance of the n-type gate electrode and the p-type gate electrode while controlling the work functions of the n-type gate electrode and the p-type gate electrode. Therefore, a higher-performance MOS field effect semiconductor device can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for fabricating a complementary MOS field effect semiconductor device, the method comprising the steps of:
forming a gate insulating film on an n-type MOS transistor formation region and a p-type MOS transistor formation region in a semiconductor layer;
forming work function control layers which differ in nitrogen concentration on the gate insulating film on the n-type MOS transistor formation region and on the gate insulating film on the p-type MOS transistor formation region; and
forming a low-resistance layer on the work function control layers.

2. The method according to claim 1, wherein in the step of forming the work function control layers which differ in nitrogen concentration on the gate insulating film on the n-type MOS transistor formation region and on the gate insulating film on the p-type MOS transistor formation region:
a metal layer in which nitrogen concentration is a predetermined value is formed on the n-type MOS transistor formation region and the p-type MOS transistor formation region;
the n-type MOS transistor formation region is masked and a predetermined amount of nitrogen is introduced into the metal layer on the p-type MOS transistor formation region; and
the metal layer on the n-type MOS transistor formation region and the metal layer on the p-type MOS transistor formation region which differ in nitrogen concentration are used as the work function control layers.

3. The method according to claim 2, wherein when the metal layer in which nitrogen concentration is the predetermined value is formed on the n-type MOS transistor formation region and the p-type MOS transistor formation region, the predetermined value is set to 5×10²¹ cm⁻³ or smaller.

4. The method according to claim 2, wherein when the n-type MOS transistor formation region is masked and the predetermined amount of nitrogen is introduced into the metal layer on the p-type MOS transistor formation region, nitrogen concentration in the metal layer on the p-type MOS transistor formation region is set to 1×10²² cm⁻³ or higher by introducing the predetermined amount of nitrogen into the metal layer.

5. The method according to claim 1, wherein in the step of forming the low-resistance layer on the work function control layers:
a first metal is used for forming a first metal layer on the work function control layer on the n-type MOS transistor formation region;
a second metal is used for forming a second metal layer on the work function control layer on the p-type MOS transistor formation region; and
the first metal layer and the second metal layer are used as the low-resistance layer.

6. The method according to claim 1, wherein the work function control layers contain at least one of HfN, ZrN, TiN, TaN, MoN, and WN.

7. The method according to claim 1, wherein a melting point of the low-resistance layer is 1,000° C. or higher.

8. The method according to claim 1, wherein the low-resistance layer contains at least one of Nb, Ta, W, Fe, Mo, Cu, Os, Ru, Rh, Co, Au, Ni, Ir, Pt, and a nitride which contains each of Nb, Ta, W, Fe, Mo, Cu, Os, Ru, Rh, Co, Au, Ni, Ir, and Pt.

9. A MOS field effect semiconductor device in which an n-type gate electrode and a p-type gate electrode formed on a gate insulating film on a semiconductor layer having an n-type active region and a p-type active region are made of a same metal and in which nitrogen concentration at an interface between the metal and the gate insulating film differs between the n-type gate electrode and the p-type gate electrode.

10. The MOS field effect semiconductor device according to claim 9, wherein nitrogen concentration in the n-type gate electrode is 5×10²¹ cm⁻³ or lower.

11. The MOS field effect semiconductor device according to claim 9, wherein nitrogen concentration in the p-type gate electrode is 1×10²² cm⁻³ or higher.

12. The MOS field effect semiconductor device according to claim 9, wherein a work function difference between the n-type gate electrode and the p-type gate electrode is 0.8 eV or more.

13. A complementary MOS field effect semiconductor device comprising an n-type gate electrode and a p-type gate electrode each having a work function control layer formed by using a same metal, the n-type gate electrode including a low-resistance layer formed on the work function control layer by using metal resistance of which is lower than resistance of the work function control layer and the p-type gate electrode including a low-resistance layer formed on the work function control layer by using metal resistance of which is lower than resistance of the work function control layer.

14. The MOS field effect semiconductor device according to claim 13, wherein the work function control layers contain at least one of HfN, ZrN, TiN, TaN, MoN, and WN.

15. The MOS field effect semiconductor device according to claim 13, wherein nitrogen concentration in the work function control layer of the n-type gate electrode is 5×10²¹ cm⁻³ or lower.

16. The MOS field effect semiconductor device according to claim 13, wherein nitrogen concentration in the work function control layer of the P-type gate electrode is 1×10²² cm⁻³ or higher.

17. The MOS field effect semiconductor device according to claim 13, wherein melting points of the low-resistance layers are 1,000° C. or higher.

18. The MOS field effect semiconductor device according to claim 13, wherein the low-resistance layers contain at least one of Nb, Ta, W, Fe, Mo, Cu, Os, Ru, Rh, Co, Au, Ni, Ir, Pt, and a nitride which contains each of Nb, Ta, W, Fe, Mo, Cu, Os, Ru, Rh, Co, Au, Ni, Ir, and Pt.

19. The MOS field effect semiconductor device according to claim 13, wherein a work function difference between the n-type gate electrode and the p-type gate electrode is 0.8 eV or more.
